(19) United States
(12) Patent Application Publication
(10) Pub. No.: US 2010/0227058 A1
(43) Pub. Date: Sep. 9, 2010

(54) Method for fabricating carbon nanotube array

(75) Inventors: Xiao-Bo Zhang, Beijing (CN); Kai-Li Jiang, Beijing (CN); Shou-Shan Fan, Beijing (CN)

Correspondence Address: PCE INDUSTRY, INC.;ATT. Steven Reiss, 288 SOUTH MAYO AVENUE, CITY OF INDUSTRY, CA, 91789, US

(73) Assignees: Tsinghua University, Beijing City (CN); HON HAI Precision Industry CO., LTD., Tu-Cheng City (TW)

(21) Appl. No.: 11/521,921

(22) Filed: Sep. 15, 2006

(30) Foreign Application Priority Data
Dec. 9, 2005 (CN) 200510102314.3

(51) Int. Cl. C23C 16/26

(52) U.S. Cl. 427/249.1; 977/843

(57) ABSTRACT

A method for fabricating a super-aligned carbon nanotube array includes the following steps: (1) providing a flat and smooth substrate (11); (2) depositing a catalyst layer (12) on the substrate at a rate of less than about 5 nm/s; (3) annealing the catalyst layer at atmosphere; (4) positioning the substrate with the catalyst layer into a furnace; (5) heating the furnace up to a predetermined temperature; and (6) supplying a reaction gas into the furnace, thereby growing a number of carbon nanotubes (22) on the substrate, via the catalyst layer, such that the carbon nanotube array is formed on the substrate.

### CROSS-REFERENCE TO RELATED APPLICATIONS

This application is related to commonly-assigned, co-pending U.S. application Ser. No. 11/484,396 entitled, “METHOD FOR MANUFACTURING CARBON NANOTUBES”, filed Jul. 11, 2006. The disclosure of the above-identified application is incorporated herein by reference.

### BACKGROUND

1. Field of the Invention

The present invention relates to a method for fabricating a carbon nanotube array and, more particularly, to a method for fabricating a super-aligned carbon nanotube array.

2. Discussion of Related Art

Since being discovered in 1991, carbon nanotubes have been synthesized by numerous methods such as laser vaporization, arc discharge, pyrolysis chemical vapor deposition, plasma-enhanced chemical vapor deposition, and/or thermal chemical vapor deposition. However, all carbon nanotubes, which have been produced by these methods, tend to be low yield, costly to manufacture, and entangled in form.

Fan et al. (Science, Vol. 283, 512-514 (1999)) discloses a method for fabricating a carbon nanotube array in an article entitled “Self-oriented regular arrays of carbon nanotubes and their field emission properties”. The method includes the steps of: providing a porous silicon wafer as a substrate; depositing a patterned iron catalyst layer on the substrate by electron-beam evaporation and annealing the substrate with the catalyst formed thereon at 300° C. at atmosphere; positioning the substrate with the catalyst in a quartz boat and placing the quartz boat with the substrate into a furnace; heating the substrate up to 700° C. in the presence of argon gas; supplying a carbon source gas (ethylene) into the furnace for 15-60 minutes; and growing a number of carbon nanotubes on the substrate from the catalyst such that a carbon nanotube array is formed on the substrate. The carbon nanotube array is perpendicular to the substrate. However, a layer of amorphous carbon is deposited on an outer surface of the carbon nanotube array during the growth process, which weakens the van der Waals interaction between adjacent carbon nanotubes. Therefore, the carbon nanotube array made by the above method typically has an unsatisfactory alignment and/or configuration. However, the aligned carbon nanotube array can be used to draw a carbon nanotube yarn, and then the carbon nanotube yarn can be used in macroscopic applications. As is shown in FIG. 3, after being ultrasonically bathed in dichloroethane for 10 minutes in order to clearly indicate individual carbon nanotube, the carbon nanotubes of the carbon nanotube array are in a tangled form and not in a aligned form.

Therefore, a method for fabricating a super-aligned carbon nanotube array with a clean smooth surface and strong van der Waals attractive force is desired.

### SUMMARY

In one embodiment, a method for fabricating a super-aligned carbon nanotube array with a clean smooth surface and strong van der Waals attractive force includes the following steps: providing a substrate having a flat and smooth surface; depositing a catalyst layer on the flat and smooth surface of the substrate, the rate of deposition of the catalyst layer being less than about 0.5 nanometers per second; and growing super-aligned carbon nanotubes directly from the catalyst layer by a chemical vapor deposition process. The chemical vapor deposition process includes the steps of: positioning the substrate with the catalyst layer thereon into a furnace; heating the furnace up to a predetermined temperature; supplying a reaction gas into the furnace; and growing a plurality of carbon nanotubes on the substrate such that the carbon nanotube array is formed on the substrate.

Other advantages and novel features of the present method for fabricating a carbon nanotube array will become more apparent from the following detailed description of preferred embodiments when taken in conjunction with the accompanying drawings.

### BRIEF DESCRIPTION OF THE DRAWINGS

A method for fabricating a carbon nanotube array can be better understood with reference to the following drawings. The components in the drawing are not necessarily drawn to scale, the emphasis instead be placed upon clearly illustrating the principles of the present method.

FIG. 1 to FIG. 3 are schematic views for illustrating the steps of manufacturing a carbon nanotube array, in accordance with a preferred embodiment;

FIG. 4 is a HRTEM (High Resolution Transmission Electron Microscope) image of the carbon nanotube array formed according to a preferred embodiment;

FIG. 5 is a TEM (Transmission Electron Microscope) image of the carbon nanotube array formed according to a preferred embodiment; and

FIG. 6 is a TEM image of the carbon nanotube array dispersed in dichloromethane according to a conventional method.

The exemplifications set out herein illustrate at least one preferred embodiment of the present method for fabricating the carbon nanotube array, and such exemplifications are not to be construed as limiting the scope of the invention in any manner.

### DETAILED DESCRIPTION OF PREFERRED EMBODIMENTS

The present method for fabricating a carbon nanotube array is further described below with reference to the drawings.

The preferred embodiment provide a method for fabricating a carbon nanotube array including the steps:

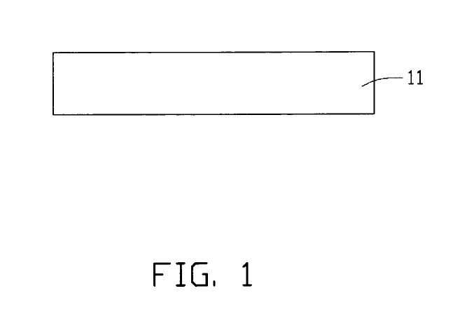

Step 1 provides a substrate with a flat and smooth surface (FIG. 1). The substrate 11 can, advantageously, be selected from the group consisting of a polished silicon wafer, a polished silicon dioxide wafer, and a polished quartz wafer. Preferably, a smoothness of the surface of the substrate 11 is less than 300 nm (nanometers) for facilitating a uniform formation of a catalyst layer directly on the substrate surface

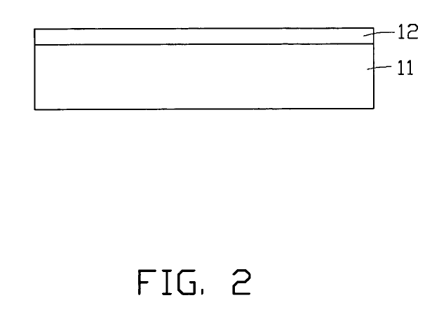

Step 2 includes the depositing of a catalyst layer on the flat and smooth surface of the substrate (FIG. 2). The catalyst layer 12 may be deposited on the surface of the substrate 11 by, e.g., electron beam evaporation or magnetron sputtering. The material of the catalyst layer 12 is, usefully, a transition metal such as iron, cobalt, nickel, or mixtures or alloys of the metals. A preferred thickness of the catalyst layer 12 is in a range of about from 3 to 6 nm and a preferred deposition rate thereof is less than about 0.5 nm/s. It is observed that the deposition rate of the catalyst layer 12 affects a density of carbon nanotubes in the produced carbon nanotube array. The thing that the deposition rate is less than 0.5 nm/s ensures the high surface density of the carbon nanotube array and a uniform diameter distribution of the carbon nanotubes thereof. It is understood, of course, that, in order for material to be deposited, the deposition rate must be a positive one (above absolute zero) during the deposition period.

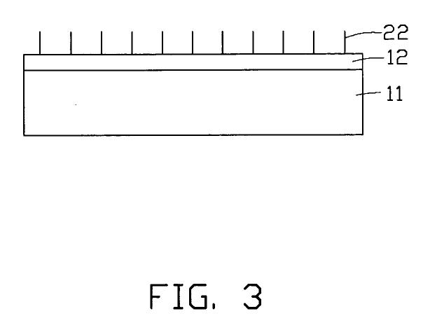

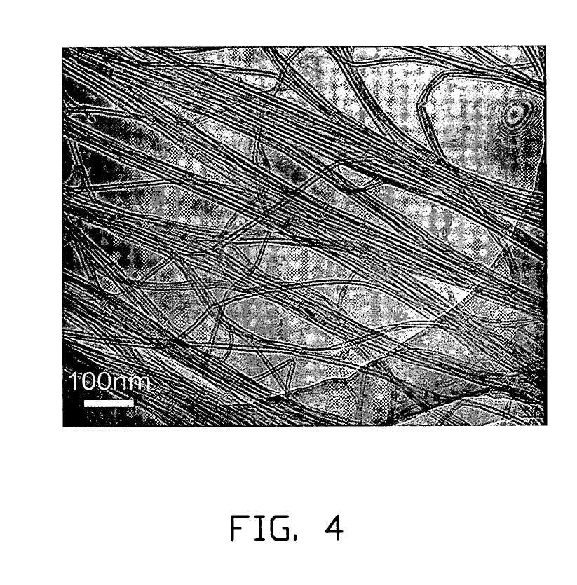

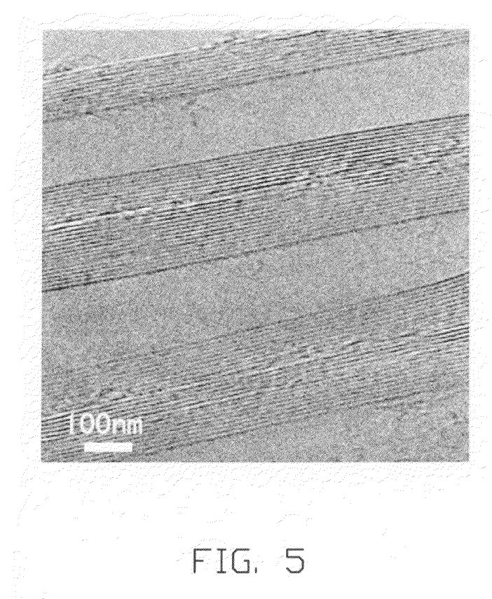

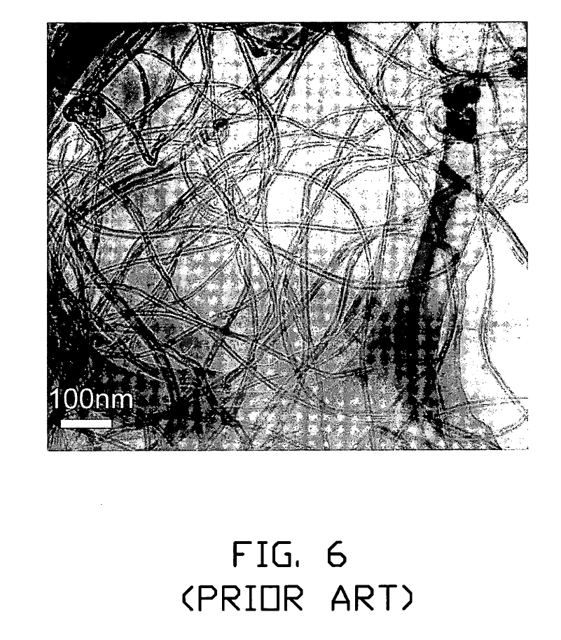

Step 3 is directed to growing carbon nanotubes on the catalyst layer formed in Step 2 (FIG. 3). In particular, the substrate, with the catalyst layer deposited thereon, is placed in a furnace, and a reaction gas is supplied into the furnace in order to grow carbon nanotubes from the catalyst layer on the substrate. Preferably, before posited in the furnace, the substrate 11, with the catalyst layer 12 deposited thereon, is annealed in ambient air at 300-400° C. for approximate 10 hours, thereby transforming the catalyst layer 12 into nano-sized catalyst oxide particles. Then, the catalyst oxide particles are then reduced to form nano-sized catalyst particles, by introducing a reducing agent such as ammonia or hydrogen. After that, the substrate 11 with nano-sized catalyst particles deposited thereon is placed into the furnace. The reaction gas is a mixture of a carbon source gas and a protecting gas. The carbon nanotubes 22, grown on the surface of the substrate 11, are obtained, with the carbon nanotubes 22 each growing from and in contact with a corresponding catalyst particle of the catalyst layer 12. The protecting gas can be, for example, hydrogen, argon, helium, nitrogen, ammonia, and/or a noble gas. The carbon source gas can, e.g., be acetylene, ethylene, and/or any other suitable hydrocarbon.

In this embodiment, a preferred growing time for the growth of carbon nanotubes is in an approximate range from 10 to 30 minutes. If the growing time is longer than 30 minutes, a potential for the deposition of amorphous carbon material is increased, and the presence of such amorphous carbon material adversely reduces a surface cleanliness of the produced carbon nanotube array and accordingly weakens the van der Waals attractive force between adjacent carbon nanotubes. If the growing time is less than 10 minutes, the produced carbon nanotubes may have a short length and thus be inconvenient for practical applications.

A temperature for growing the carbon nanotubes is preferably about in a range from 620° C. (Celsius degrees) to 750° C. If the temperature is lower than 620° C., a growth rate of carbon nanotubes is lowered, which adversely affects the surface density of the carbon nanotubes. If the temperature is higher than 750° C., the deposition rate of amorphous carbon tends to be increased.

The methods for fabricating the carbon nanotube array by AP-CVD (Atmospheric Pressure Chemical Vapor Deposition) and LP-CVD (Low Pressure Chemical Vapor Deposition) are illustrated in the following two embodiments.

The carbon nanotube array is fabricated by AP-CVD in one embodiment. The approximate pressure range of AP-CVD is 10-760 Torr. In the present embodiment, a polished silicon wafer having a polished surface is used as a substrate, iron is used as a catalyst, and a mixture of hydrogen and acetylene is used as a reaction gas. Specifically, an iron film of approximately 3-6 nm thick is deposited on (i.e., in contact with) the polished surface of the substrate (i.e. polished silicon wafer) at an approximate deposition rate of 0.01 nm/s by electron beam evaporation. The substrate with the iron catalyst is placed into a quartz tube furnace; hydrogen gas is introduced into the quartz tube furnace; and the quartz tube furnace is heated up to about 620-700° C. Then, an acetylene gas is supplied into the furnace for about 5-30 minutes. Thus, a super-aligned carbon nanotube array is formed on the substrate.

Further process variables are associated with this embodiment, in which the carbon nanotube array is formed via AP-CVD. A gas pressure in the quartz tube furnace is retained at approximate 760 torr (i.e., at essentially atmospheric pressure) in the growth process of the carbon nanotube array. A flux of the acetylene gas is about 30 sccm (Standard Cubic Centimeter per minute), and a flux of the hydrogen gas is about 300 sccm. A flux ratio of the carbon source gas (e.g., acetylene gas) relative to the protecting gas (e.g., hydrogen gas) should be in a range of about from 0.1% to 10% in the present embodiment. A content of the carbon source gas in the reaction gas (i.e., a molar ratio of carbon source gas to protecting gas) determines, in part, the deposition rate of amorphous carbon. The lower content of the carbon source gas, the lower deposition rate of amorphous carbon. Advantageously, a preferred molar ratio of carbon source gas to protecting gas is kept at less than about 5% by adjusting the flux of each gas. As such, the carbon nanotubes produced above have a clean and smooth outer surface, and strong van der Waals attractive forces exist between adjacent carbon nanotubes, which enable the carbon nanotubes to be compactly bundled up together.

In another embodiment, the carbon nanotube array is fabricated by LP-CVD. The pressure range of LP-CVD is about 0.1-10 torr. In the present embodiment, polished silicon is used as substrate, iron is used as catalyst, and acetylene is used as reaction gas. An iron catalyst film of about 3-6 nm in thickness is deposited on the substrate at a deposition rate of about 0.01 nm/s by magnetron sputtering. The substrate with the catalyst is put into a quartz tube furnace and then heated up to 680-750° C., approximately. After that, acetylene gas, at a flux of about 300 sccm, is supplied into the furnace for approximately 10-20 minutes. Thus, a super-aligned carbon nanotube array is formed on the substrate. The pressure in the furnace is retained at 2 torr in the growth process of the carbon nanotube array. The growth of carbon nanotube by LP-CVD requires a substantial flow from a carbon source gas. In the present embodiment, the reaction gas can be a pure carbon source gas or a mixture of the carbon source gas and less than about 5% of the protecting gas. The step of growing carbon nanotube by LP-CVD can further includes a step of accumulating an amount of amorphous carbon on the sidewall of the furnace before the growing step.

Referring to FIG. 2 and FIG. 3, the super-aligned carbon nanotube array is obtained in the preferred embodiments using AP-CVD or LP-CVD. The carbon nanotubes are well graphitized and almost have no amorphous carbon formed on the outer surface thereof. Therefore, the van der Waals attractive forces between adjacent carbon nanotubes are strong, and the carbon nanotubes can be compactly bundled up together. Furthermore, if desired, a carbon nanotube yarn can be pulled out in linked bundles from the super-aligned carbon nanotube array and then can be applied in a macroscopic application.

It is noted that the pressure is not necessary limited to the above given ranges. The super-aligned carbon nanotube array can potentially be made at any appropriate pressure range, by adjusting factors such as the flux ratio of the carbon source gas to the protecting gas.

Finally, it is to be understood that the embodiments mentioned above are intended to illustrate rather than limit the invention. Variations may be made to the embodiments without departing from the spirit of the invention as claimed. The above-described embodiments illustrate the scope of the invention but do not restrict the scope of the invention.

1. A method of fabricating a carbon nanotube array, comprising steps of:
providing a substrate having a flat and smooth surface;
depositing a catalyst layer on the surface of the substrate at a positive deposition rate of less than 0.01 nanometers per second;
growing super-aligned carbon nanotubes directly from the catalyst layer, such growing be achieved by a chemical vapor deposition process;
wherein the chemical vapor deposition process is conducted at a low pressure in range from about 0.1 to about 10 torr and executed in a furnace; and the chemical vapor deposition process comprises a step of supplying a reaction gas into the furnace; and when supplying the reaction gas, no other gases are introduced into the furnace; wherein the reaction gas is a pure hydrocarbon gas.

2. The method as claimed in claim 1, further comprising a step of annealing the catalyst layer at atmosphere prior to the growing step.

3. The method as claimed in claim 1, wherein the substrate is selected from the group consisting of a polished silicon wafer, a polished silicon dioxide wafer, and a polished quartz wafer.

4. The method as claimed in claim 1, wherein the chemical vapor deposition process comprises steps of: positioning the substrate with the catalyst layer into a furnace; and heating the furnace up to a predetermined temperature before supplying the reaction gas into the heated furnace, thereby growing a plurality of carbon nanotubes, via the catalyst, on the substrate such that the carbon nanotube array is formed on the substrate.

5-6. (canceled)

7. The method as claimed in claim 1, wherein the hydrocarbon gas is selected from the group consisting of acetylene and ethylene.

8. The method as claimed in claim 1, wherein a thickness of the catalyst layer is about in a range from 3 to 6 nanometers.

9-14. (canceled)

15. The method as claimed in claim 1, further comprising a step of accumulating amorphous carbon on the sidewall of the furnace before the growing step.

16. The method as claimed in claim 2, wherein the catalyst layer is transformed into catalyst oxide particles by annealing the catalyst layer.

17. The method as claimed in claim 16, further comprising forming nano-sized catalyst particles from the catalyst oxide particles after annealing the catalyst layer.

18. The method as claimed in claim 17, wherein the catalyst oxide particles are reduced to form nano-sized catalyst particles by introducing a reducing agent.

19. The method as claimed in claim 18, wherein the reducing agent is ammonia or hydrogen.

20. The method as claimed in claim 1, wherein the growing time of the super-aligned carbon nanotube is in a range of about 10 minutes to 20 minutes.

21. A method of fabricating a super-aligned carbon nanotube array, comprising steps of:
providing a substrate having a surface;
depositing a catalyst layer on the surface of the substrate;
positioning the substrate with the catalyst in a furnace;
heating the furnace to a predetermined temperature;
supplying a reaction gas into the furnace, wherein the reaction gas is a pure hydrocarbon gas;
growing a plurality of carbon nanotubes on the substrate such that the carbon nanotube array is formed on the substrate, wherein the step of growing a plurality of carbon nanotubes on the substrate is achieved by a chemical vapor deposition process, the chemical vapor deposition process is conducted at a pressure in a range from about 0.1 to about 10 ton and at a temperature for growing carbon nanotubes in a range from about 680° C. to about 750° C.

22-26. (canceled)

27. The method as claimed in claim 1, wherein a temperature for growing the super-aligned carbon nanotubes is in a range from about 680 to about 750° C.

28. The method as claimed in claim 1, wherein the carbon nanotubes are well graphitized with little if any amorphous carbon formed on the outer surface thereof.

29. The method as claimed in claim 1, wherein the super-aligned carbon nanotubes are compactly bundled together.
